(19) United States
(12) Patent Application Publication
(10) Pub. No.: US 2025/0208171 A1
(43) Pub. Date: Jun. 26, 2025

(54) ONE HANDED TEST LEADS HOLDER TOOL AND APPARATUS FOR ONE HANDED TESTING OF AN ELECTRICAL DEVICE

(71) Applicant: John Riccitelli, San Jose, CA (US)

(72) Inventor: John Riccitelli, San Jose, CA (US)

(21) Appl. No.: 18/898,427

(22) Filed: Sep. 26, 2024

Related U.S. Application Data
(60) Provisional application No. 63/614,315, filed on Dec. 22, 2023.

(51) Int. Cl. G01R 15/00

(52) U.S. Cl. CPC G01R 15/00

(57) ABSTRACT

In one example, a one handed holder apparatus includes a first elongated arm having a first holder at a first distal region to hold a first test lead, a second elongated arm having a second holder at a first distal region to hold a second test lead, a lever disposed on the first elongated arm or the second elongated arm and a pivot to pivotally couple the first elongated arm to the second elongated arm to allow a user to control and position the first test lead and the second test lead with one hand based on pressing or releasing of the lever to test electrical parameters of an electrical device without having electrical current accidentally entering or passing through a body of the user.

### CROSS-REFERENCE TO RELATED APPLICATION

This application claims the benefit of U.S. Provisional Application No. 63/614,315, filed on Dec. 22, 2023 entitled: “One Handed Test Leads Holder”, the contents of which are incorporated by reference herein.

### FIELD

Embodiments of the present disclosure relate to electrical test tools including a one handed test leads holder tool, a test leads holder apparatus, and test leads holder of a voltmeter test instrument for one handed testing of an electrical device.

### BACKGROUND

Voltmeters and multi-meters are commonly used to check the amount of voltage, resistance, or continuity between two points. Generally, a voltmeter or multimeter has two test leads each connected to the voltmeter or multimeter with wires. To check for voltage or make an electrical test an operator (e.g., an electrician, user) needs to touch each test lead to the different points on the equipment being tested. The operator can then look at the voltmeter or multimeter and determine the voltage or other readings present between the two points.

The danger occurs when an operator needs to use such a voltmeter or multimeter to check voltages above 40 volts or so, which is very common in most electrical work. It is very dangerous to hold a lead in each hand and perform a test, and yet is very difficult to hold both leads in only one hand (as users are told to do). This is further complicated if the operator doing the testing needs to also hold the voltage meter itself in one of their hands.

### SUMMARY

The present disclosure allows an operator to hold the two separate test leads and a test instrument itself with one hand, while performing electrical test operations of an electrical device. The operator simply attaches a test leads holding tool to their test instrument (e.g., voltmeter, multi-meter, ammeter, etc.) and attaches the test leads to each arm of the test leads holding tool.

In one example, a one handed test leads holder tool includes a first arm having a first holder at a distal region to hold a first test lead; a second flexible arm having an extendable or removable arm and a second holder at a distal region to hold a second test lead; a first handle for the first arm; a second handle for the second flexible arm; and a pivot to pivotally couple the first arm to the second flexible arm to allow a user to control positioning of the first test lead and the second test lead with one hand while holding the first and second handles to test electrical parameters of an electrical device without having electrical current accidentally entering or passing through a body of the user.

In another example, a one handed holder apparatus includes a first elongated arm having a first holder at a first distal region to hold a first test lead, a second elongated arm having a second holder at a first distal region to hold a second test lead, a lever disposed on the first elongated arm or the second elongated arm and a pivot to pivotally couple the first elongated arm to the second elongated arm to allow a user to control and position the first test lead and the second test lead with one hand based on pressing or releasing of the lever to test electrical parameters of an electrical device without having electrical current accidentally entering or passing through a body of the user.

In another example, a test leads holder for attachment to a handheld test instrument includes an adapter frame, a test lead holder arm to pivot with respect to the adapter frame via a pivot and being adapted at a first distal region to hold a first test lead, an extendable holder arm being adapted to hold a second test lead, and a lever formed at a second distal region of the test lead holder arm. A user adjusts a spacing between the first distal region of the test lead holder arm and a distal region of the extendable holder arm by pressing or releasing the lever with a digit of one hand to control a position of the first test lead and the second test lead to test voltage of an electrical device without having electrical current accidentally entering or passing through a body of the user.

Other embodiments are also described. Other features of embodiments of the present present disclosure will be apparent from the accompanying drawings and from the detailed description which follows.

### BRIEF DESCRIPTION OF THE DRAWINGS

The embodiments of the present disclosure are illustrated by way of example and not by way of limitation in the Figures of the accompanying drawings in which like references indicate similar elements. It should be noted that references to “an” or “one” embodiment of the present disclosure in this disclosure are not necessarily to the same embodiment, and they mean at least one.

Following is a brief description of the drawings with reference numbers.

FIG. 1A illustrates a front view of a ‘scissor’ style of a ‘one handed voltage meter and test leads holder’ in accordance with one embodiment.

FIG. 1B illustrates a side view of the ‘scissor’ style of the ‘one handed voltage meter and test leads holder’ in accordance with one embodiment. The voltmeter/multi-meter adapter/holder is attached to the lead holder of FIG. 1A, and both are assembled as one unit.

FIG. 2 illustrates a front view of the ‘scissor’ style of the ‘test leads holder’ apparatus, showing the removable flexible arms, the optional longer flexible extension arm, and the adapter/holder for a voltmeter/multi-meter in accordance with some embodiments.

FIG. 3A shows the steps of attaching the test leads holder, voltmeter/multi-meter adapter/holder, and voltmeter/multi-meter to adapter/holder in accordance with one embodiment.

FIG. 3B illustrates the ‘scissor’ style of the ‘one handed test leads holder’ when all three separate pieces are assembled 146 as one unit in accordance with one embodiment.

FIG. 4 illustrates a front view of the ‘scissor’ style of the ‘one handed test leads holder’ apparatus in accordance with one embodiment.

FIG. 5 illustrates a front view of the ‘scissor’ style of the ‘one handed voltage meter and test leads holder’ with the adapter/holder being attached to the leads holder apparatus with bolts and washers in accordance with one embodiment.

FIG. 6 illustrates a side view of the ‘scissor’ style of the ‘test leads holder’ with the adapter/holder/boot attached in accordance with one embodiment. On the right side of FIG.-6 is the unattached adapter/holder for a voltmeter/multi-meter.

FIG. 7 illustrates a front view of the ‘scissor’ style of the ‘test leads holder’ with two typical test leads, attached to the non-metallic clips in accordance with one embodiment.

FIG. 8 illustrates a front view showing the ‘scissor’ style of the ‘test leads holder’ all as one unit in accordance with one embodiment.

FIG. 9A illustrates a front view of the ‘scissor’ style of the ‘test leads holder’ apparatus, in the closed position (demonstrating what the device looks like when pressure is applied to handles) in accordance with one embodiment.

FIG. 9B illustrates a side view of the ‘scissor’ style of the ‘test leads holder’ of FIG. 9A in accordance with one embodiment, which shows the pivot stud holding the two arms together.

FIG. 10 illustrates a side view of the ‘scissor’ style of the ‘test leads holder’ of FIG. 9-A, with the two arms ‘disconnected’ from each other in accordance with one embodiment.

FIG. 11A illustrates a front view of the ‘scissor’ style of the ‘test leads holder’ with two flexible arms, as well as two optional longer flexible extension arms, in the extended position in accordance with some embodiments.

FIG. 11B illustrates a side view of the ‘scissor’ style of the ‘test leads holder’ with two flexible arms, as well as two optional longer flexible extension arms in accordance with some embodiments.

FIG. 12 illustrates a side view of the ‘scissor’ style of the ‘test leads holder’ with the pivot stud removed from one arm, and the two arms disconnected from each other in accordance with some embodiments.

FIG. 13 illustrates a front view of the ‘tongs style’ embodiment of the ‘one handed test leads holder’, which shows the pivot stud attaching the pivoting ‘leads holder’ arms together.

FIG. 14 illustrates a front view of the ‘tongs style’ embodiment of the ‘one handed test leads holder’ with the voltmeter/multi-meter adapter attached.

FIG. 15 illustrates a front view of a ‘small metal frame’ embodiment of the ‘one handed test leads holder’ in which pressing the 154 lever triggers an adjustment to a distance the leads holders are apart from one another.

FIG. 16 illustrates a front view of the ‘small metal frame’ embodiment of the test leads holder, with the voltmeter adapter attached.

FIG. 17 illustrates a front view of the ‘small metal frame’ embodiment of the test leads holder, with the test leads holder and voltmeter/multi-meter all as one unit.

FIG. 18 illustrates a front view of the ‘small metal frame’ embodiment of the test leads holder, with the test leads holder and voltmeter/multi-meter all as one unit. Typical test leads are attached to the lead holder arms.

FIG. 19 illustrates a typical voltmeter being used in typical ‘two’ handed operation, without the convenience of the ‘one handed test leads holder’.

FIG. 20 illustrates a live electrical test being performed using only one hand in accordance with one embodiment, as opposed to the two handed operation as shown in FIG. 19.

FIG. 21 illustrates a back view of the ‘scissor’ style of the ‘one handed leads holder’ in accordance with one embodiment in which the test leads holder and voltmeter/multi-meter are shown all as one unit. Also showing test leads attached to the test lead clips.

FIG. 22 illustrates a back view of the ‘small metal frame’ embodiment of the test leads holder in accordance with one embodiment in which the test lead clips pivot away from each other when the user presses the lever trigger.

FIG. 23 illustrates a back view of the ‘tongs style’ embodiment of the test leads holder in which the test lead holder arms pivot closer together when the user presses the lever trigger.

FIG. 24 illustrates a front view of the ‘tongs style’ embodiment of the one handed test leads holder apparatus that includes one flexible and extendable arm with a tightening nut and sleeve.

FIG. 25 illustrates a front view of the flexible extension arms in accordance with one embodiment, and the telescoping extension tubes, which are kept in the extendable arm sleeve.

### DETAILED DESCRIPTION

All references cited herein are incorporated herein in their entireties. If there is a conflict between a definition herein and in an incorporated reference, the definition herein shall control. At least one of A, B, and C refers to a selection of A alone, B alone, C alone, a combination of A and B, a combination of A and C, a combination of B and C, or a combination of A and B and C.

### Definitions

Voltage: Voltage, also known as potential difference, electric pressure, or electric tension is the difference in electric potential between two points. In a static electric field, it corresponds to the work needed per unit of charge to move a positive test charge from the first point to the second point. Voltage is the electric pressure from an electrical circuit's power source that pushes charged electrons (current) through a conducting loop, enabling the electrons to do work such as illuminating a light. In brief, voltage=pressure, and it is measured in volts.

Electrical Safety: Recognizing hazards associated with the use of electrical energy and taking precautions so that hazards do not cause injury or death. Voltage testing is a common procedure when working with electricity, yet electric voltage and current can be very dangerous and fatal if precautions are not followed. A common rule in electrical voltage tests with meters is to use only one hand to hold both test leads, as voltage and current are most dangerous when they pass through the arms from one arm to the other as the electricity naturally tries to find a path of least resistance which is generally the other end of the two test points. When holding one test lead in each hand the users body becomes the shortest path to the other test lead if the wires are faulty in any way or if the users hand touches a live test point. The greatest danger is that during an electrical test the electricity could pass through the users heart while going from one arm to the other arm resulting in electrocution or ventricular fibrillation of heart. When current flows through the human body, it can cause a lot of problems. Currents as low as 10 mA can cause severe muscle contractions and burns, while currents of 20 mA or greater can cause paralysis of the muscles that allow you to breathe. If a current from outside the body passes through the heart, it can mask these impulses and disturb the heart's rhythm. This irregular heartbeat is called arrhythmia and can even manifest as a total disorganization of the rhythm, known as ventricular fibrillation.

Voltage testing: Voltage is needed to operate most any electrical circuit or device and so it is a very common test when checking electrical and or electronic equipment. Voltage testing is an essential procedure that should be completed before carrying out any work on an electrical installation. Ensuring the absence of voltage can be vital for safety reasons and the main purpose is to limit the risks that live electrical circuits and equipment can pose to individuals.

Multimeter definitions: The most common handheld electrical test instruments are voltmeters, multimeters, and ammeters. Handheld ammeters, are most commonly called ‘clamp on meters’ or just ‘clamp meters’ because the jaws open and close to go around electrical cables. Voltmeters are most commonly called multimeters as most are digital rather than analog, and they have ‘multiple’ functions. Analog meters are still common but just not as popular with professionals who need multiple test functions, and or a variety of electrical tests to perform. Analog and digital meters are generally similar in shape and design, and both are used in the same way to do electrical tests, so a one handed leads holder would work with either meter and would benefit the user of either meter.

Voltmeter meter/Voltage meter: An instrument for measuring electric potential in volts. Typically, the voltmeter has a digital or analog screen to see and read the value in volts. Typically, the voltmeter or voltage meter has two test leads which are attached to the meter with wires. The wires are generally two to three feet in length and have metal tips on the ends of the test leads to make contact with a test point. The test leads are generally plugged into various ports on the meter depending on what type of test is being conducted. Generally, if not always, only two wires are needed to do a voltage test with a meter.

Multimeter: An instrument designed to measure electric current, voltage, and usually resistance, typically over several ranges of value.

Ammeter: An instrument for measuring electric current in amperes. Typically, the ammeter has a digital or analog screen to display the measured values in amperes.

Clamp on ammeter/clamp meter: is a clothespin-shaped instrument that can be clamped around a live wire in order to measure the current being carried by the live wire. As a measurement principle, clamp meters detect the magnetic field emitted by current flowing in a wire in order to measure the current value. The clamp meters generally have nonmetallic jaws that open so that the clamp meters can be put onto a piece of wire without disconnecting the wire, and the amperage is then displayed on the screen of the ammeter when it is set to read amperes.

Test lead: An insulated wire that connects a test instrument, such as a voltmeter, multimeter, ammeter or an oscilloscope, to the device under test (DUT). Test leads are typically used to measure voltage, current, and resistance, among other electrical characteristics. Test instruments and test leads are a temporary connection to electrical systems, often live at the time, for the purpose of making measurements to establish or confirm various parameters of electrical equipment.

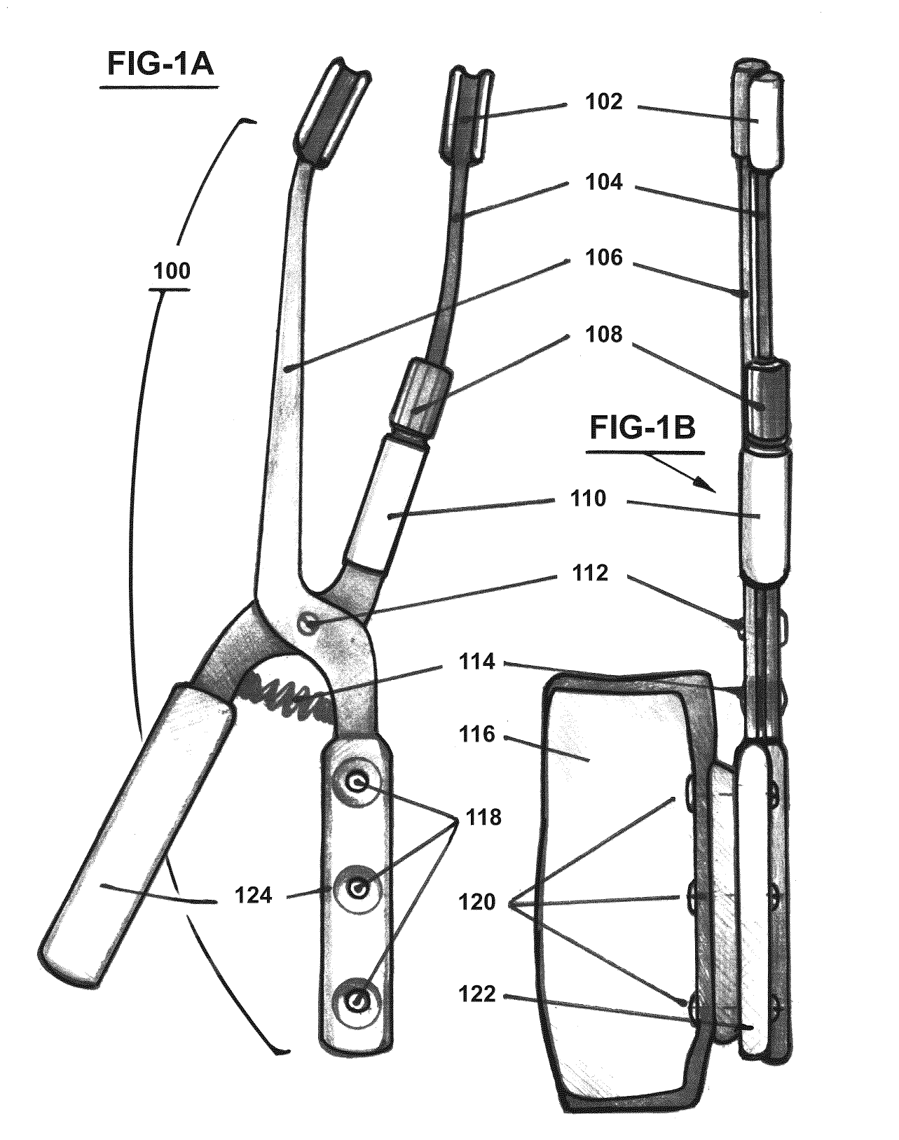

### REFERENCE NUMBERS FOR FIGS. 1A-25

100—Detailed drawing of ‘one handed voltage meter and test leads holder’
102—Non-metallic clips to hold test leads.
104—Flexible arm.
106—Stationary arm.
108—Extendable arm/removable arm tightening nut.
110—Extendable arm sleeve.
112—Pivot stud.
114—Spring.
116—Voltmeter/multi-meter adapter/holder.
118—Adapter holes for bolts.
120—Adapter bolts, washers and nuts.
122—Adapter spacer.
124—Hand grips.
126—Removable flexible arms and adapter.
128—Short flexible extension arm.
130—Optional longer flexible extension arm.
132—Adapter/holder for voltmeter/multi-meter.
134—Bolt holes for attaching test leads holder to adapter.
136—Squeezing hand grips together moves test leads together.
138—Drawing: showing the three steps of attaching pieces together.
140—Step one: Attach the two test leads onto the arms of test leads holder.
142—Step two: Attach leads holder to voltmeter/multi-meter adapter/holder.
144—Step three: Attach voltmeter/multi-meter to adapter/holder.
146—Test leads holder and voltmeter/multi-meter all as one unit.
148—Voltmeter
150—Pivoting test lead holder arm
152—Frame for voltmeter/multi-meter adapter with holes for adapter bolts.
154—Lever trigger for opening and closing arms of the leads holders.
156—Screw for attaching extendable arm sleeve.
158—Typical test leads for voltmeter.
160—Test points demonstrating typical electrical voltage test.
162—Showing one handed operation of leads ‘one handed leads holder’ design
164—Showing typical two-handed operation without design during a typical electrical test
166—Pivoting leads holder arms
168—Flexible flat spring attachment screws
170—Flexible flat spring
172—Adapter washer
174—Telescoping extension tubes

### Technical Solution

This present disclosure allows a person to hold two separate test leads and an electrical test instrument (e.g., voltmeter, multimeter, ammeter) with one hand, while performing electrical test operations. The user simply attaches this novel test leads holding tool to their voltmeter/multi-meter and attaches the test leads to each arm of the test leads holder tool. This allows a user to position, adjust, and control, both test leads using a finger level trigger of the tool, while using the tool with one hand.

A one handed test leads holder tool connects to a test instrument. In one example, the shape of this tool is similar to a pair of scissors, pliers, or wire strippers. The one handed test leads holder tool opens and closes with a squeeze of the handles as illustrated in FIGS. 1A and 1B. The handles are connected with a pivot screw 112 and tension is provided by a biasing mechanism 114 (e.g., spring 114).

FIG. 1A illustrates a front view of the ‘scissor’ style of the ‘one handed voltage meter and test leads holder’ in accordance with one embodiment. FIG. 1A shows the apparatus of the leads holder 100 without the attachable holder/boot 116. FIG. 1B on the right, is a side view, with the holder/boot 116 attached using three bolts. By applying pressure to the handles 124, the test lead holders 102, come together. One of the test lead holder 102 is affixed to the flexible arm 104 and the other test lead holder is affixed to the stationary arm 106 of the scissor like apparatus. The extendable arm/removable arm tightening nut 108 allows the flexible arm 104 to extend out from the extendable arm sleeve 110, for a longer reach when desired. The two arms are attached to one another with the pivot stud 112. The spring 114 keeps the arms apart, and the spring also gives a slight resistant pressure to control movement when the handles 124 are squeezed together. The lever action works much like a common electrician's wire stripper, either closing or opening the distance between the two arms of the leads holders. Typical electrical test leads (not shown) are placed in the lead holder clips and a voltmeter or multimeter (not shown) is placed in the holder 116 (shown on the right in FIG.-1B).

FIG. 1B illustrates a side view of the ‘scissor’ style of the ‘one handed voltage meter and test leads holder’ in accordance with one embodiment. The voltmeter/multi-meter adapter/holder 116 is attached to the lead holder apparatus of FIG. 1A, and both are assembled as one unit. The voltmeter/multi-meter adapter/holder is attached to the handle 124 with bolts 120 that pass through the adapter holes 118 on the handle 124, and then through the spacer 122, and connect the voltmeter/multi-meter adapter/holder to the leads holder apparatus 100, making the two pieces one unit. A voltmeter/multi-meter (not shown) can then be placed in the holder/boot 116.

An adapter spacer 122 provides a spacing between the adapter/holder 116 and the tool 100. Hand grips 124 provide a user with a fatigue reducing surface to grip the tool 100. The test leads holder tool can be shaped like scissors with a flexible clip to hold the test leads. The test leads are held by the tension of the flexible clips on the ends of the tools two arms 102. The arms open wider with a squeeze of the handles 124. Pressure can also be put on the handles by attaching the leads holder to the voltmeter and then squeezing one handle with the meter in the same hand. The leads holder can be made to attach to the voltmeter so that the leads holder and test instrument can be one unit. An adapter that attaches the leads holder to the voltmeter using bolts, washers and a spacer is shown in the drawings.

In one example, the test leads holder tool is made as follows. The tool is shaped like a pair of scissors or wire strippers with two long arms that pivot so that the arms can move the attached test leads wider or closer together. The two test leads click into the test leads holder tool on distal ends of the two arms. One arm can be made to be flexible 104, and or, extend out with a telescopic like tube 110 for more reach. The other arm can remain stationary 106. This leads holder tool can be electrically insulated or coated with non-metallic materials such as plastic, carbon fiber or rubber.

This test leads holder tool can also be made with a wire stripper and wire cutting edges between the arms for convenience.

In one example, a leads holder tool is attached to a rubber voltmeter/multi-meter adapter. Then, a voltmeter/multi-meter is placed into the adapter. Next, test leads are attached to the arms of the leads holder. The arms of the tool can be extended or bent to make the easiest or safest contact with test points. FIG. 1A illustrates the ‘scissor’ style embodiment of the test leads holder, without the attachable holder/boot 116.

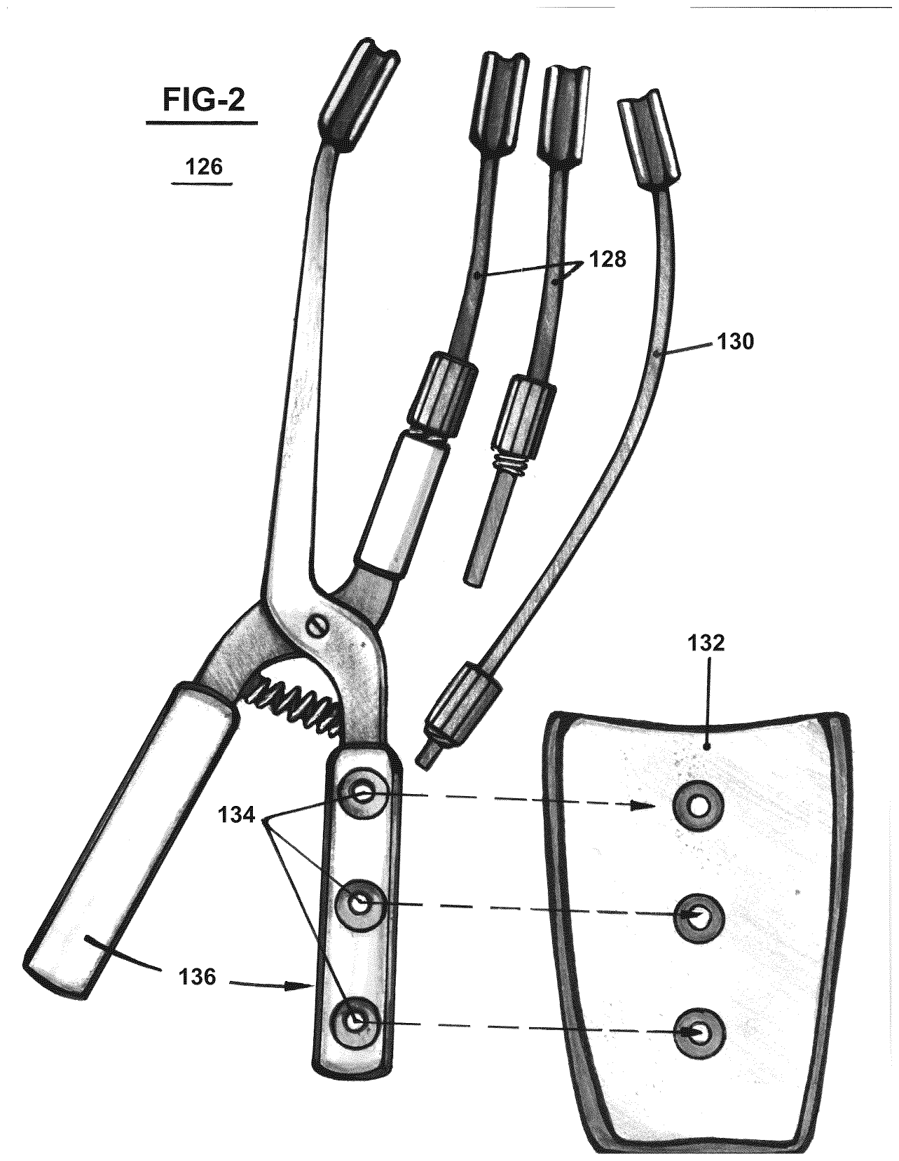

FIG. 2 illustrates a front view of the ‘scissor’ style of the ‘test leads holder’ apparatus in accordance with some embodiments, showing the removable flexible arms, the optional longer flexible extension arm 130, and the adapter/holder 132 for a voltmeter/multi-meter. Also showing the bolt holes 134 for attaching the test leads holder to the adapter/holder for a voltmeter/multi-meter (attachment bolts and voltmeter are not shown). Squeezing the hand grips 136 of the handles together moves the holders 102 (e.g., non-metallic test lead clips 102) closer together. The removable flexible arm 128 can be unscrewed from the sleeve and replaced with an optional longer flexible extension arm, if so desired by the user. These optional attachable arm lengths do not detract or change the initial purpose of moving the test leads closer or further apart. The arms can bend or extend if needed to reach test points. The additional lengths are to better suit the different situations a user may encounter in electrical testing environments.

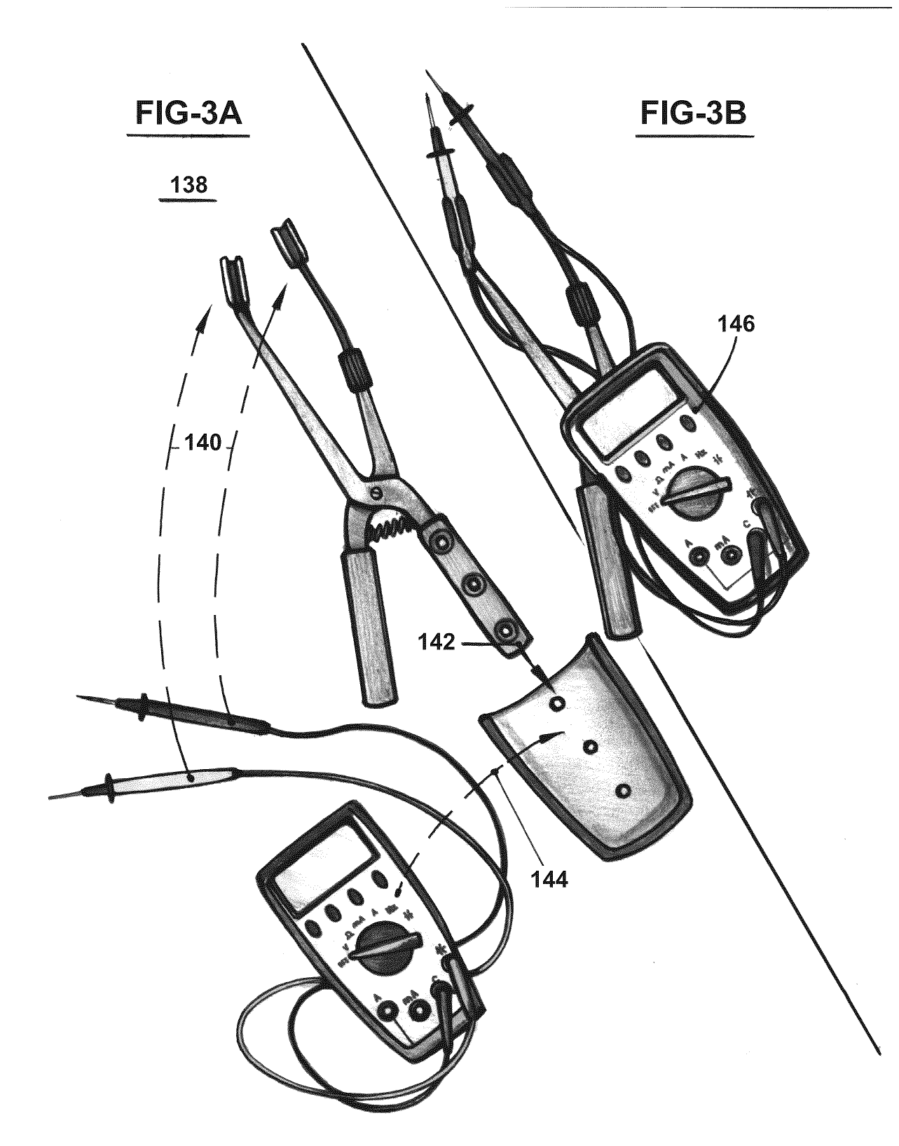

FIG. 3A shows steps or operations of attaching different holder and test leads components together in accordance with one embodiment. At operation 140, a user attaches the two test leads onto the arms of test leads holder. At operation 142, the user can attach leads holder to a voltmeter/multi-meter adapter/holder. At operation 144, the user can attach the voltmeter/multi-meter to the adapter/holder. The apparatus can be manufactured together as a complete unit as illustrated in FIG. 3B, or it can be manufactured as it is illustrated in FIG. 3A as separate components or parts primarily so that a user can use their existing voltmeter/multi-meter, and simply place it in the adapter holder. The user's existing test leads are also meant to clip into the leads holder apparatus. The test leads holder apparatus is meant to work with the user's existing voltmeter/multi-meters and test leads.

FIG. 3B illustrates the ‘scissor’ style of the ‘one handed test leads holder’ in accordance with one embodiment when all three separate components or parts are assembled 146 as one unit. When all three components or parts are assembled as one unit, the user can perform electrical tests safely and easily using one hand. By adjusting the length and angle of the flexible and extendable arms of the apparatus, the user can reach electrical test points that are far apart, or close together.

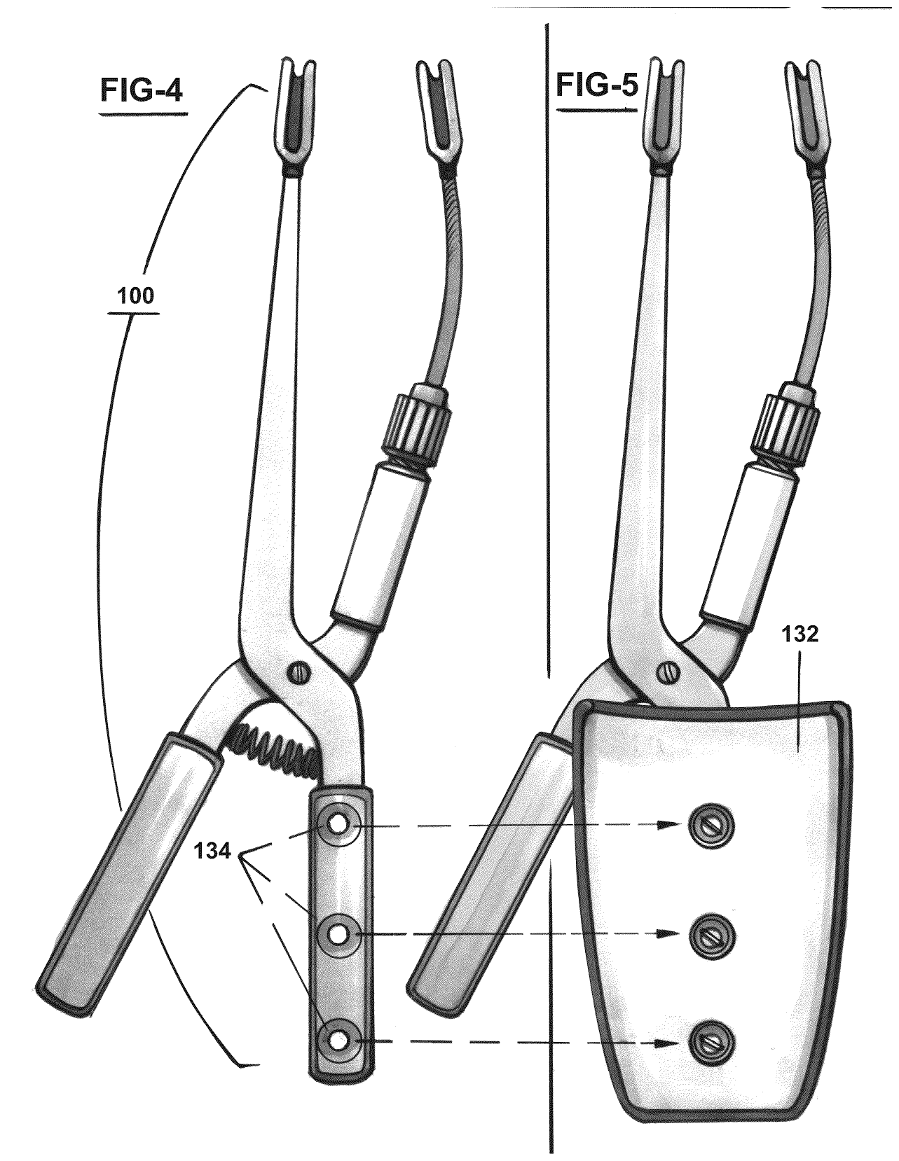

FIG. 4 illustrates a front view of the ‘scissor’ style of the ‘one handed test leads holder’ apparatus in accordance with one embodiment. The holes 134 on the handle end of the scissor like arm of the leads holder apparatus are for passing bolts/screws through, in order to attach the adapter/holder 132 shown in FIG. 5. The number of bolts, screws or attachment points are not specifically of importance. The adapter/holder 132 is easily enough attached to the leads holder apparatus and secure enough to properly be used. Other forms of attachment are possible in the embodiments. The purpose and use of the apparatus is not reliant on the means of attachment.

FIG. 5 illustrates a front view of the ‘scissor’ style of the ‘one handed voltage meter and test leads holder’. The adapter/holder 132 is attached to the leads holder apparatus with bolts and washers. The ‘test leads holder’ and the ‘adapter/holder’ are thus attached together as one unit. A voltmeter/multi-meter can then be placed into the adapter/holder. The adapter/holder fits whatever common voltmeter model, or brand, the user may have. Accessory holders can be made to fit a variety of styles of voltmeters and multimeters. These holders or boots are generally made of rubber or plastic. Holders and boots are generally made flexible and tight enough to hold a voltmeter securely.

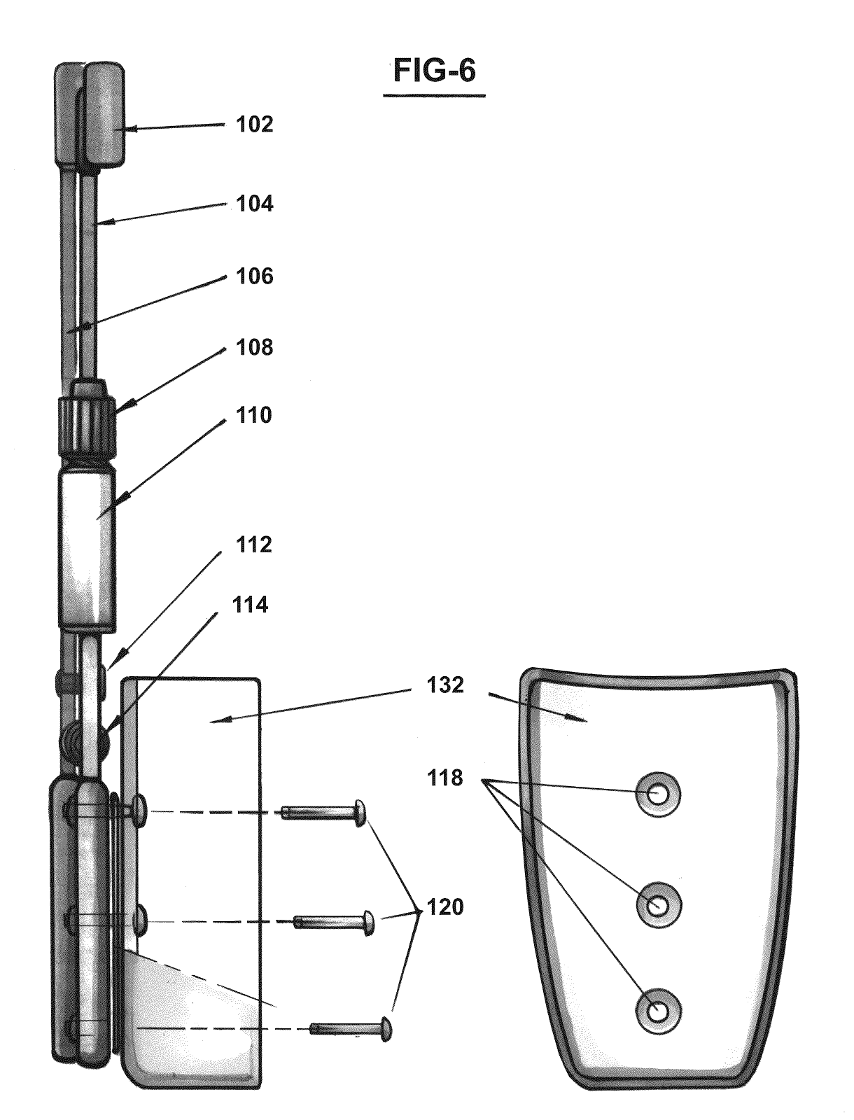

FIG. 6 illustrates a side view of the ‘scissor’ style of the ‘test leads holder’ apparatus in accordance with one embodiment, with the adapter/holder/boot attached using bolts/screws. This embodiment has one flexible arm 104 and one stationary arm 106. The stationary arm of this embodiment only means it is not necessarily flexible or extendable. The stationary arm needn't be flexible or extendable in most common test situations, but it may be desirable to have both arms extendable (as shown in other embodiments) for certain test situations the user may encounter. The extendable arm/removable arm tightening nut 108, and the extendable arm sleeve 110, are in the forefront of FIG. 6. The pivot stud 112, and the spring 114, are just below the extendable arm sleeve. The bolts/screws 120 go through the holes 118 of the adapter/holder 132. On the right side of FIG. 6 is the unattached adapter/holder 132 for a voltmeter/multi-meter.

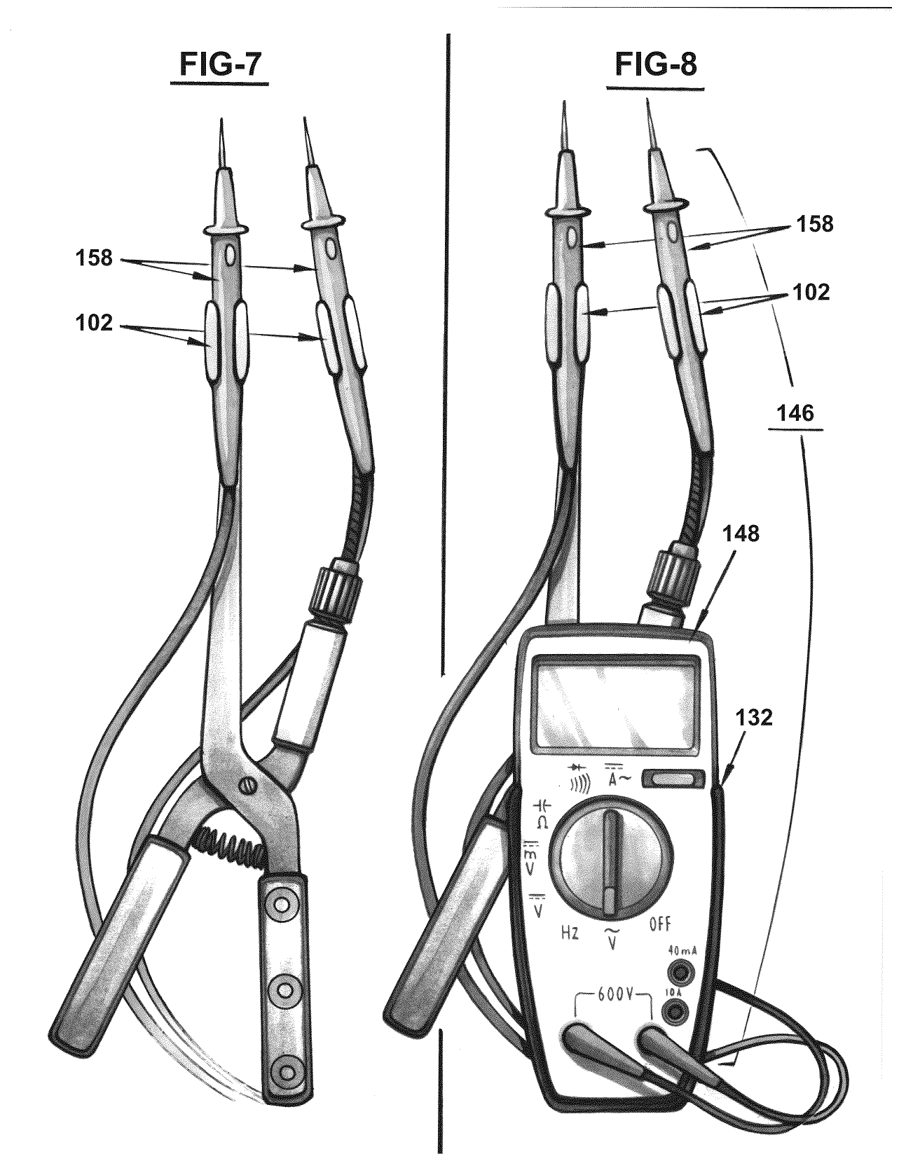

FIG. 7 illustrates a front view of the ‘scissor’ style of the ‘test leads holder’ apparatus in accordance with one embodiment, with two test leads 158, attached to the non-metallic clips 102. The one handed test leads holder apparatus can be used to conduct electrical tests using one hand in this form. The test leads can be brought together to touch electrical test points with only one hand controlling the test leads apparatus. With the test leads 158 attached to the leads holders 102, as illustrated here, the test leads apparatus can be used with one hand to perform tests. The user may want to use the leads holder without the voltmeter/multimeter attached, having only the test leads attached as here in FIG. 7. The user may choose to hold the voltmeter/multimeter in their other hand, but the most dangerous problem is overcome by not having to hold the test leads one in each hand. Holding the voltage meter in the other hand is not a dangerous health risk, as is the former. Safety is improved based on having the ability to visually focus on both the voltmeter and the test leads when both are held together as one unit. The user can accidentally shift their eyes away from the leads when looking at the meter readings, and thus it becomes a hazard. When the voltmeter/multimeter is attached to the leads holder it is safer and easier to focus on both at the same time while conducting electrical tests as shown in FIG. 8.

FIG. 8 illustrates a front view showing the ‘scissor’ style of the ‘test leads holder’ apparatus in accordance with one embodiment, all as one unit, with two test leads 158 attached to the non-metallic clips 102. A voltmeter 148 is placed in the adapter/holder 132. With the test leads connected to the test leads holder apparatus, and the adapter/holder attached to the test leads apparatus, and a typical voltmeter/multimeter 148 placed in the adapter/holder, the user can then hold and operate all the components or parts together with one hand.

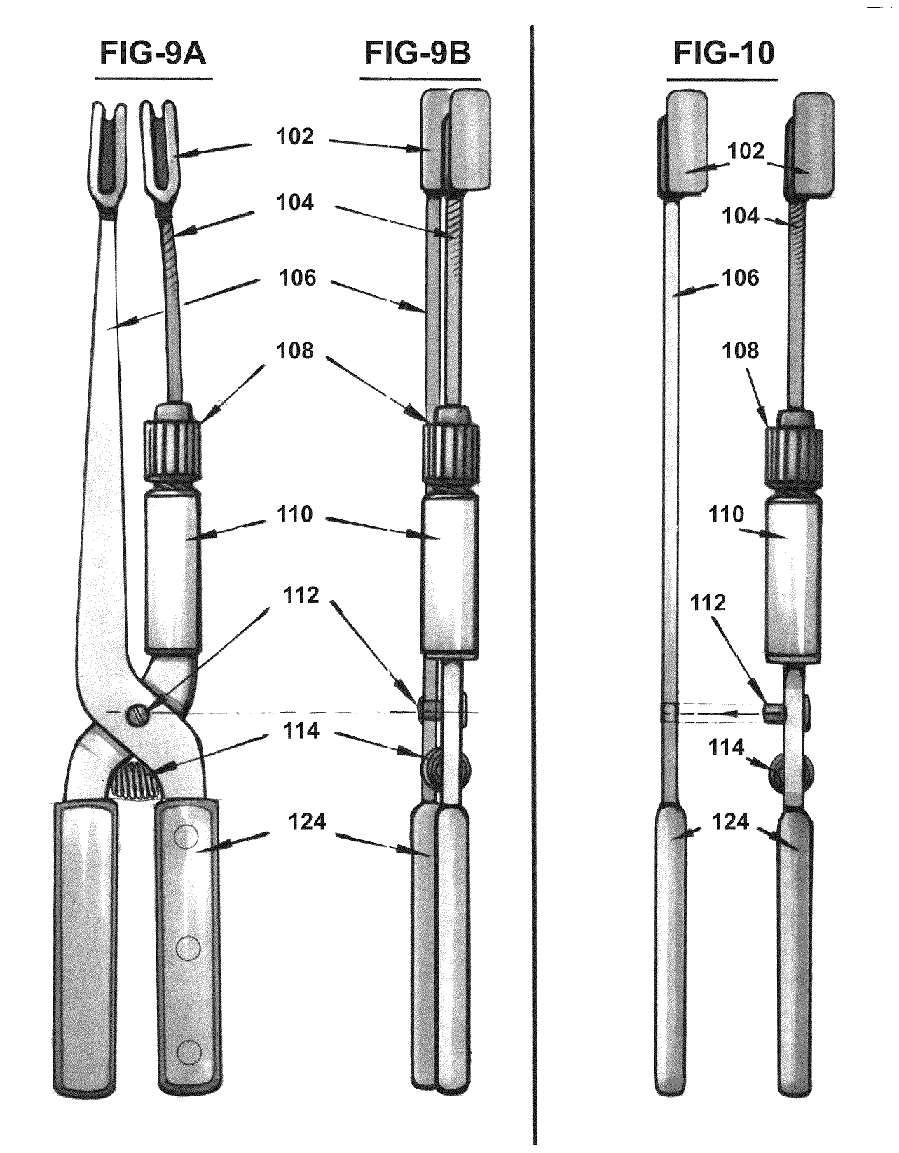

FIG. 9A illustrates a front view of the ‘scissor’ style of the ‘test leads holder’ apparatus in accordance with one embodiment, showing the non-metallic clips 102, affixed to the flexible arm 104, as well as the stationary arm 106. The extendable arm/removable arm tightening nut 108 and the extendable arm sleeve are attached to one of the arms of the leads holder apparatus, shown here in the closed position. The 112 pivot stud holds the two arms together. The 114 spring puts tension on the two arms to keep them open, and to provide some resistance when squeezing the handles together. The extendable arm is not shown in extended position.

FIG. 9B illustrates a side view of the ‘scissor’ style of the ‘test leads holder’ apparatus of FIG. 9A. The 112 pivot stud holds the two arms together.

FIG. 10 illustrates a side view of the ‘scissor’ style of the ‘test leads holder’ apparatus of FIG. 9A in accordance with one embodiment, with the two arms ‘disconnected’ from each other. The two arms are connected to each other with a 112 pivot stud/screw. The means of attaching the two arms together are simply what is common to most scissor or cutting tools that have arms opposed and or attached to one another. The 112 pivot stud and the 114 spring are just below the 110 extendable arm sleeve.

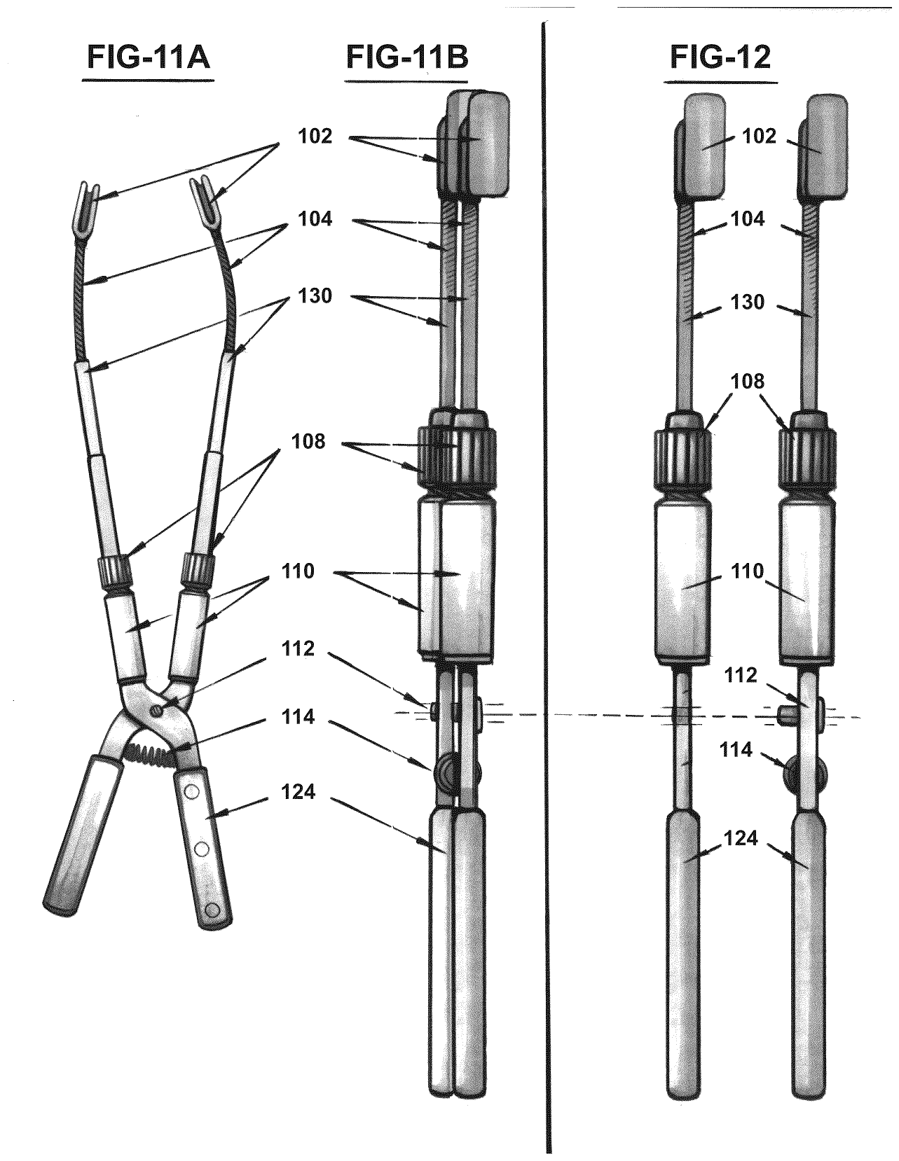

FIG. 11A illustrates a front view of the ‘scissor’ style of the ‘test leads holder’ in accordance with some embodiments. The preceding ‘scissor’ style embodiments have only one flexible extension arm, where FIG. 11A illustrates an embodiment having two flexible arms 104, as well as two optional longer flexible extension arms 130. Each arm of this embodiment has a non-metallic clip 102, an extendable arm/removable arm tightening nut 108, and an extendable arm sleeve 110. This embodiment allows for more reach, versatility, safety, and ease of use for performing electrical tests. The pivot stud 112 and the spring 114 are just below the extendable arm sleeve 110. The hand grips 124 are typical of electrical wire strippers, or other similar small hand tools.

FIG. 11B illustrates a side view of the ‘scissor’ style of the ‘test leads holder’ in accordance with some embodiments with two flexible arms 104, as well as two optional longer flexible extension arms 130. Noting the pivot stud 112 holds the two arms together, and allows the lead holder arms to open and close.

FIG. 12 illustrates a side view of the ‘scissor’ style of the ‘test leads holder’ in accordance with some embodiments with the pivot stud/screw removed from one arm 112, and the two arms disconnected from each other. This leads holder embodiment has two flexible arms 104, as well as two optional longer flexible extension arms 130. The right and left arms of the apparatus are basically the same having holes for the pivot stud 112, and notches to secure the spring 114. One handle 124 may have holes, or an attachment point, for the voltmeter/multimeter adapter/holder.

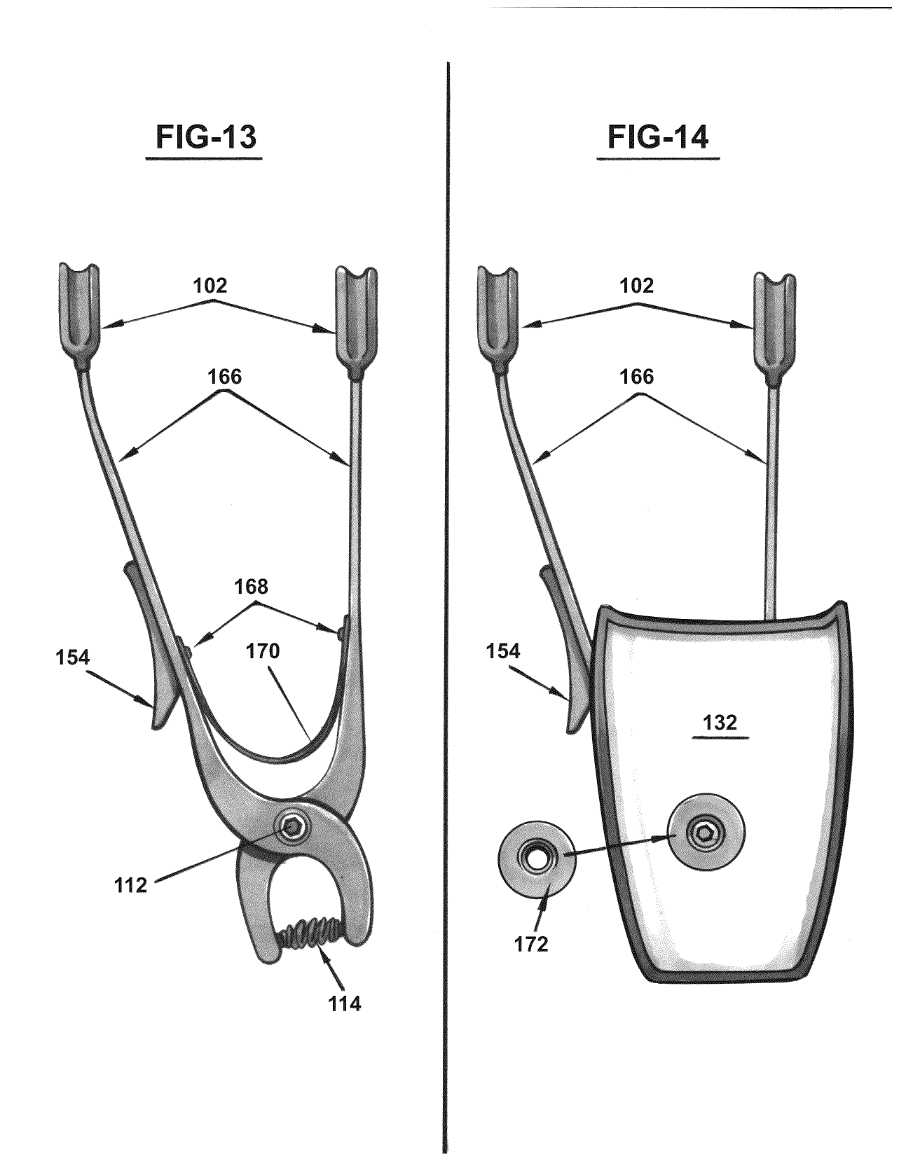

FIG. 13 illustrates a front view of the ‘tongs style’ embodiment of the ‘one handed test leads holder’. The tongs embodiment of the leads holder is a simplified form of the preceding leads holder embodiment, but the function is the same as in the preceding and the following embodiments. The function of the ‘one handed test leads holder’ being that the elongated arms of the apparatus can be opened, closed, or held in differing positions with just one hand. The tongs embodiment allows the user to use the upper index, thumb and upper fingers of the palm for controlling position of the test leads, where the other preceding embodiment the user is apt to use their lower fingers. The different embodiments give the user options fitting their own preference and or ease of use. The test lead holder/clips 102 are affixed near upper distal ends of the pivoting lead holder arms 166. The elongated arms are held in the open wide position by both the flexible flat spring 170, and the spring 114. In one example, the flexible flat spring 170 is disposed between an intermediate region of the first elongated arm and an intermediate region of the second elongated arm to hold the first and second elongated arms in an open wide position. The spring 114 is disposed between a lower distal end of the first elongated arm and a lower distal end of the second elongated arm to hold the first and second elongated arms in an open wide position.

The two pivoting ‘leads holder’ arms 166 come together by putting finger pressure on the lever 154. The pivot stud 112 attaches the pivoting ‘leads holder’ arms 166 together. The flexible flat spring 170 is attached to the ‘lead holder’ arms with the flexible flat spring attachment screws 168. The use of one, or two springs, or even another form of tension, to keep the arms open or adjustable, is not pertinent to the function of the design.

FIG. 14 illustrates a front view of the ‘tongs style’ embodiment of the ‘one handed test leads holder’ with the voltmeter adapter attached 132. The Adapter/holder 132 for a voltmeter/multi-meter is attached to the leads holder apparatus with the washer and pivot bolt/screw 172. As in FIG. 13, the test lead holder clips 102 are affixed to the pivoting lead holder arms 166. The two pivoting leads holder arms 166 come together by putting finger pressure on the lever 154. A voltmeter/multi-meter (not shown) can then be placed in the holder 132, and test leads (not shown) can then be clipped onto the test lead holder clips 102.

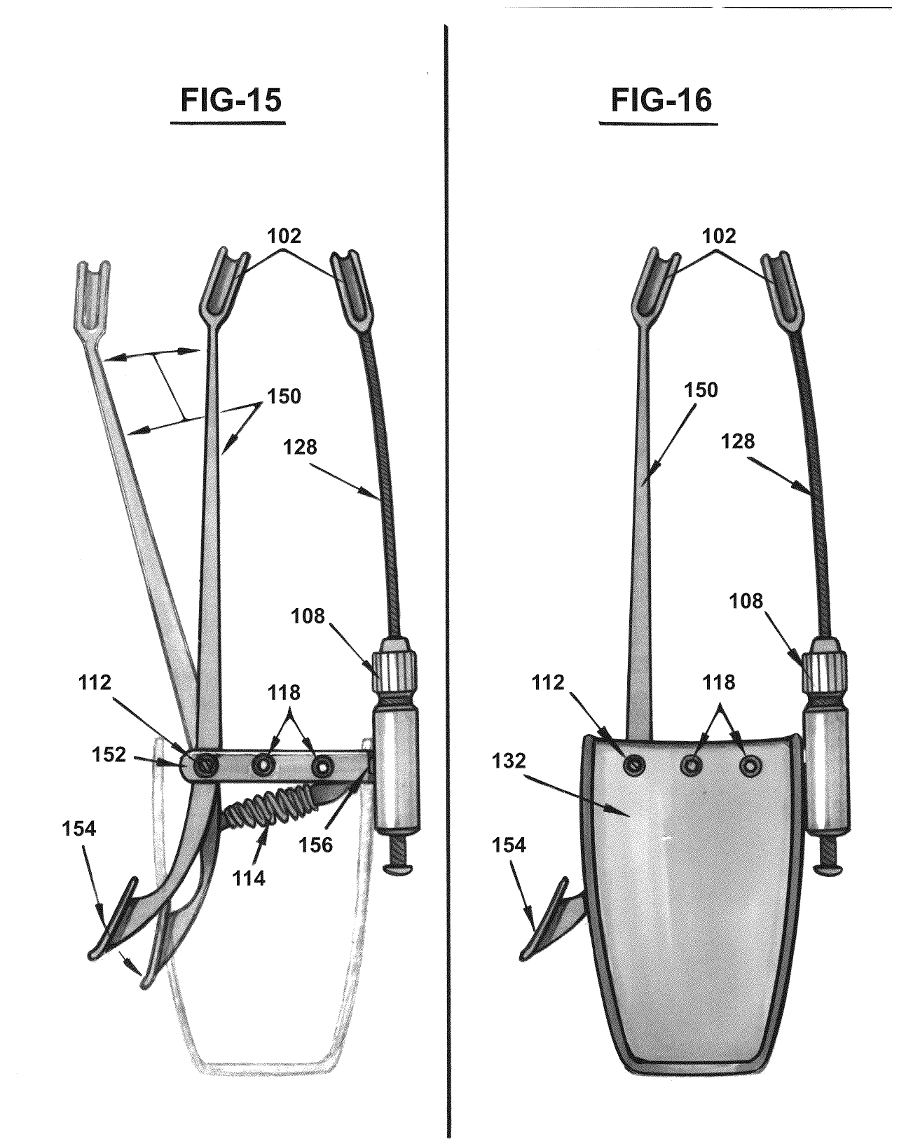

FIG. 15 illustrates a front view of a metal frame embodiment of the ‘one handed test leads holder’. The small frame embodiment of the leads holder is a different form of the preceding leads holder embodiments, but the function is the same as in the preceding and the following embodiments. The function being that the arms of the apparatus can be opened, closed, or held in differing positions with just one hand. This embodiment has an adapter frame 152, with holes 118 for adapter bolts, and a hole for the pivot stud 112. The pivoting test lead holder arm 150 is attached to the adapter frame 152 with the pivot stud 112. This drawing shows the movement of the test leads holder arm 150. The extendable arm, nut and sleeve 108 are attached to the frame with a screw 156 for attaching the extendable arm sleeve. By pressing the lever 154 (shown in two positions), the user can adjust the distance the leads holders are apart from one another, in order to make contact with electrical test points during an electrical test. This embodiment has non-metallic test lead holder clips 102 affixed to both arms. Any of the embodiments can be held and operated in either of the users right or left hand, or reversed to be a left or right handed version without affecting any function or purpose of the tool. In one example, the lever is formed at a lower distal end of the test leads holder arm 150.

FIG. 16 illustrates a front view of the metal frame embodiment of the test leads holder, with the voltmeter adapter attached. The adapter/holder 132 for voltmeter/multi-meter is attached to the metal frame 152 with adapter bolts, washers and nuts 120. A voltmeter/multi-meter (not shown) can then be placed in the holder 132 and test leads (not shown) can then be clipped onto the test lead clips 102.

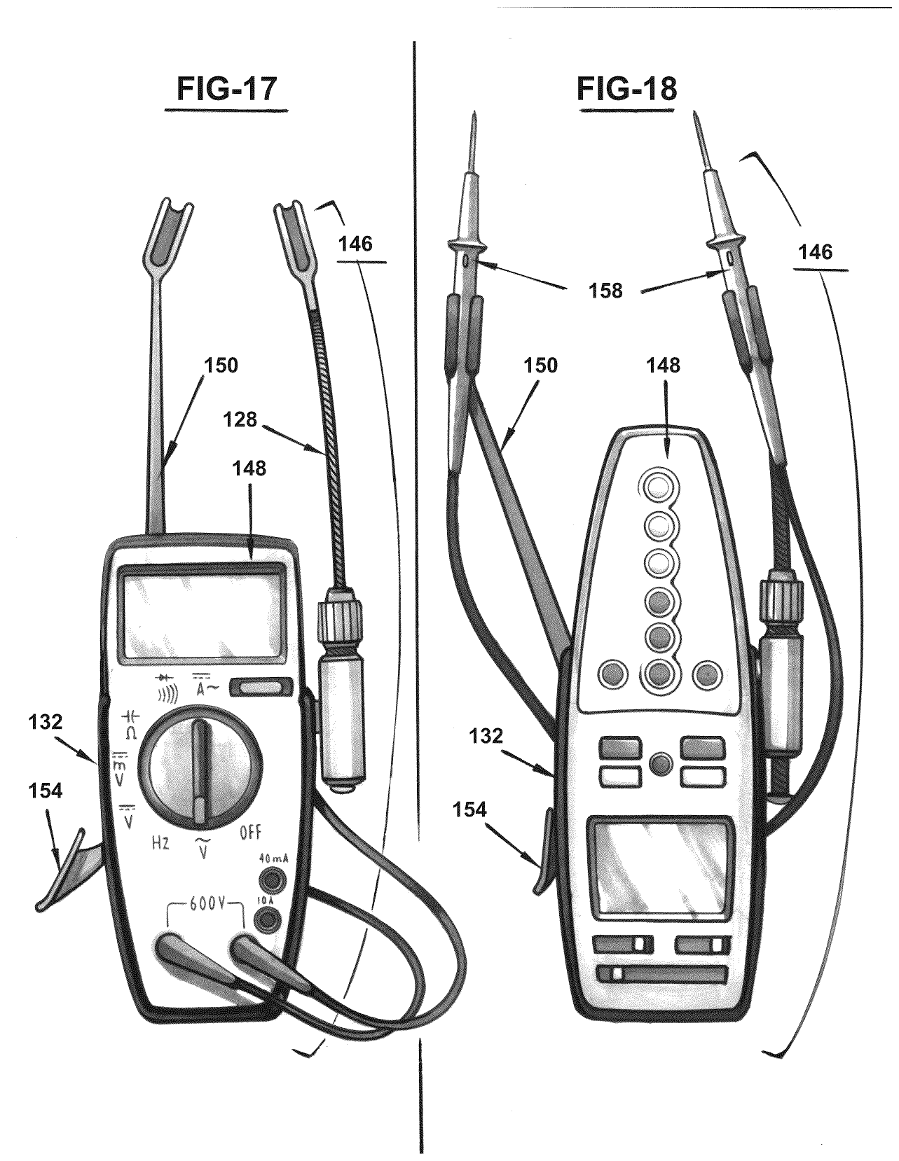

FIG. 17 illustrates a front view of the metal frame embodiment of the test leads holder, with the test leads holder and voltmeter/multi-meter all as one unit. The pivoting arm 150 is shown in the default position, since there is no pressure on the lever 154 (e.g., finger lever 154). A voltmeter 148 is attached using the voltmeter adapter/holder 132. Typical test leads (not shown) can then be attached to the test lead holders.

FIG. 18 illustrates a front view of the metal frame embodiment of the test leads holder, with the test leads holder 146 and voltmeter/multi-meter all as one unit. Typical test leads 158 for a voltmeter are attached to the pivoting arm 150 and flexible lead holder arm 128. This drawing is showing that a different version of a typical voltmeter 148 can be attached using the voltmeter adapter 132. Voltmeters and multi-meters come in a variety of shapes, but most are typical of these two shapes. Adapters and holders can be made to hold each brand or shape without much change to the leads holder. By pressing the lever 154, the user can adjust the distance the leads holders are apart from one another in order to make contact with electrical test points during an electrical test.

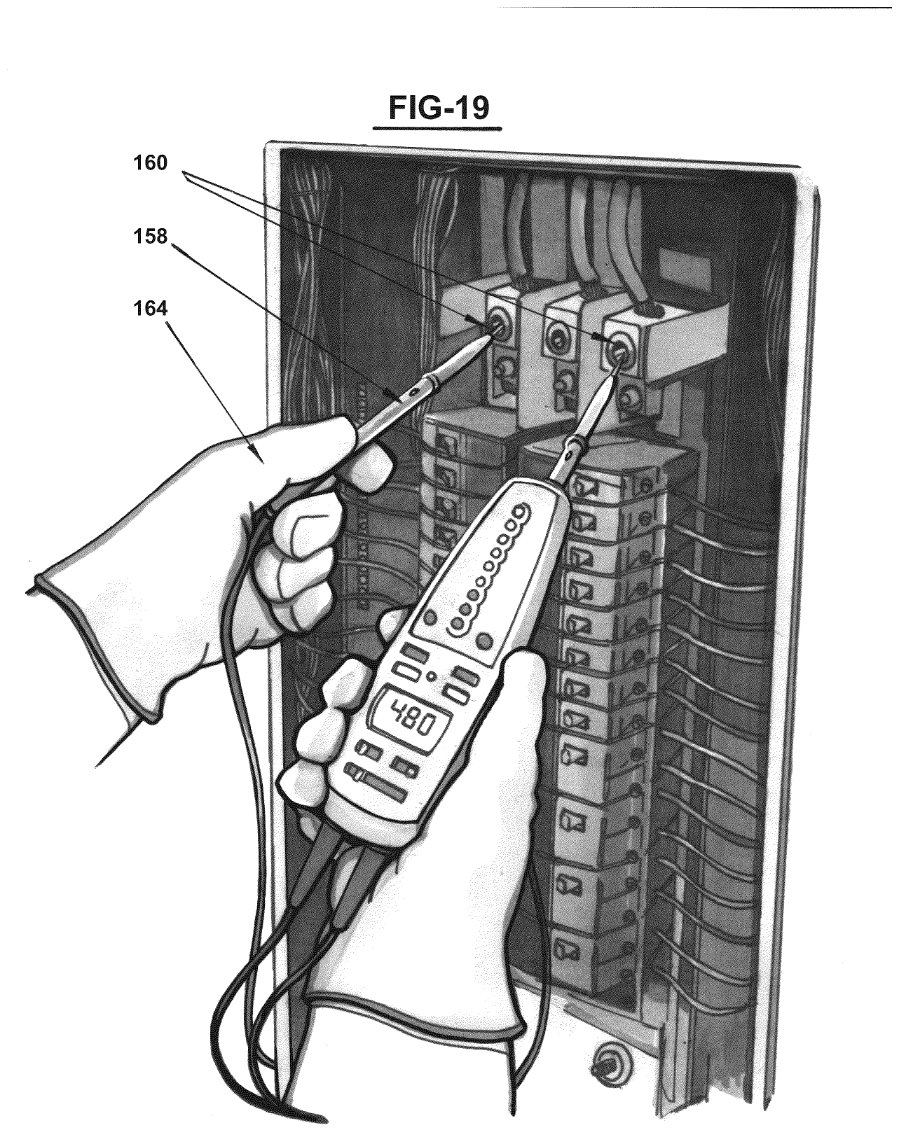

FIG. 19 illustrates a typical voltmeter being used in typical two handed operation, without the convenience of the one handed test leads holder. The test points 160 are contacted using typical test leads 158. With one hand holding both the voltmeter and a test lead, the other hand typically holds the other test lead while touching a live electrical test point. Note, FIG. 19 shows the safety issue and what the one handed apparatus is designed to solve. The one handed leads holder intends to make it safer and more convenient for the user while testing live electrical systems. The case and convenience also add to the safety of conducting live electrical tests.

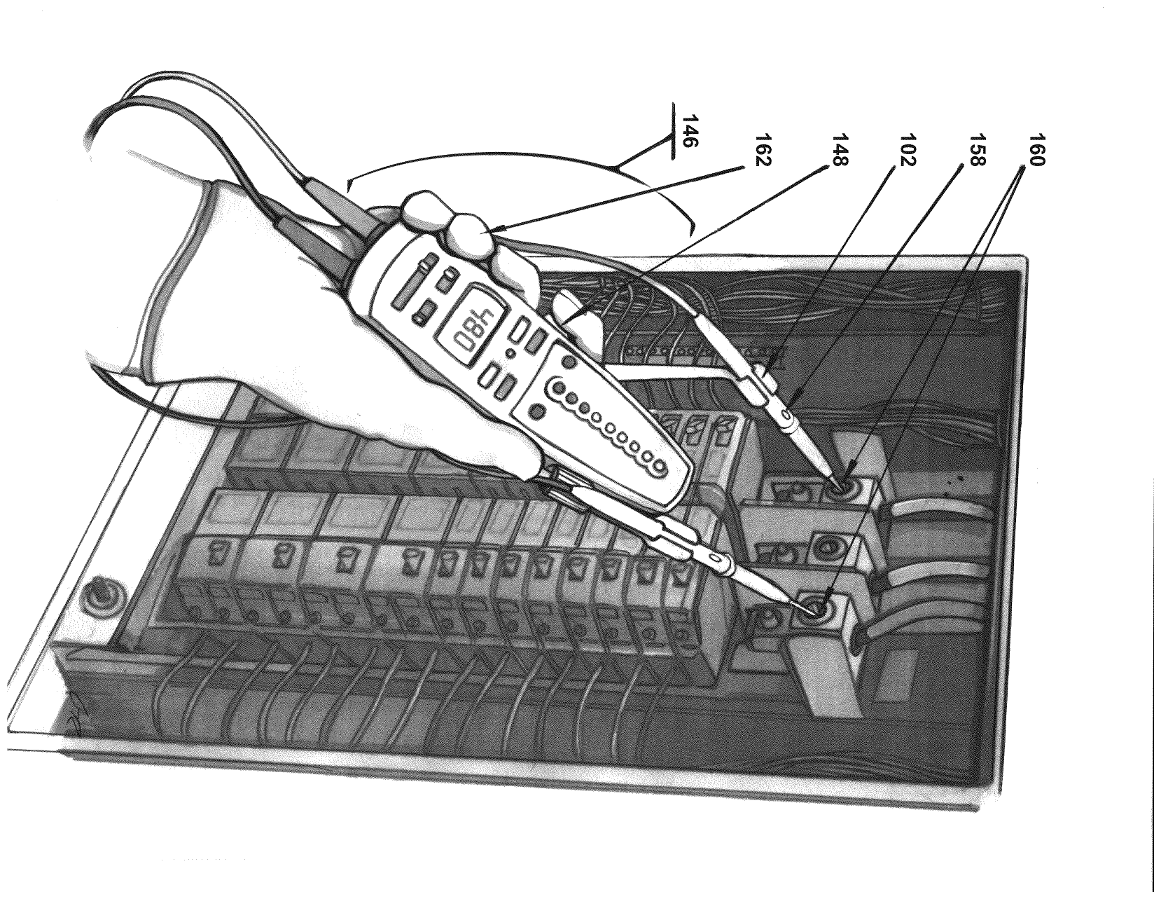

FIG. 20 illustrates a live electrical test done using only one hand in accordance with some embodiments, as opposed to the two handed operation as shown in FIG. 19. FIG. 20 shows that a typical electrical test, can be accomplished with only one hand using this tool. One hand can hold both the voltmeter and control positioning of the two test leads safely and with case, while touching a live electrical test point. The test points 160 are touched, using typical test leads 158, attached to the leads clips 102, using a typical voltmeter 148. FIG. 20 shows the one handed operation, as well as the test leads holder 146 and voltmeter/multi-meter all as one unit.

FIG. 21 illustrates a back view of the ‘scissor’ style of the ‘one handed leads holder’ in accordance with one embodiment. The test leads holder 146 and voltmeter/multi-meter are shown all as one unit. Typical test leads 158 are attached to the test lead clips 102. One arm has a short flexible extension 128. A typical voltmeter 148 is held by the voltmeter/multi-meter adapter/holder 132.

FIG. 22 illustrates a back view of the metal frame embodiment of the test leads holder. The test lead clips 102 pivot away from each other when the user presses the Lever 154. The adapter frame 152 is attached to the adapter/holder 132 for a voltmeter/multi-meter. A typical voltmeter/multi-meter 148 is placed in the adapter/holder 132. Typical test leads (not shown) can be attached to the test lead clips 102.

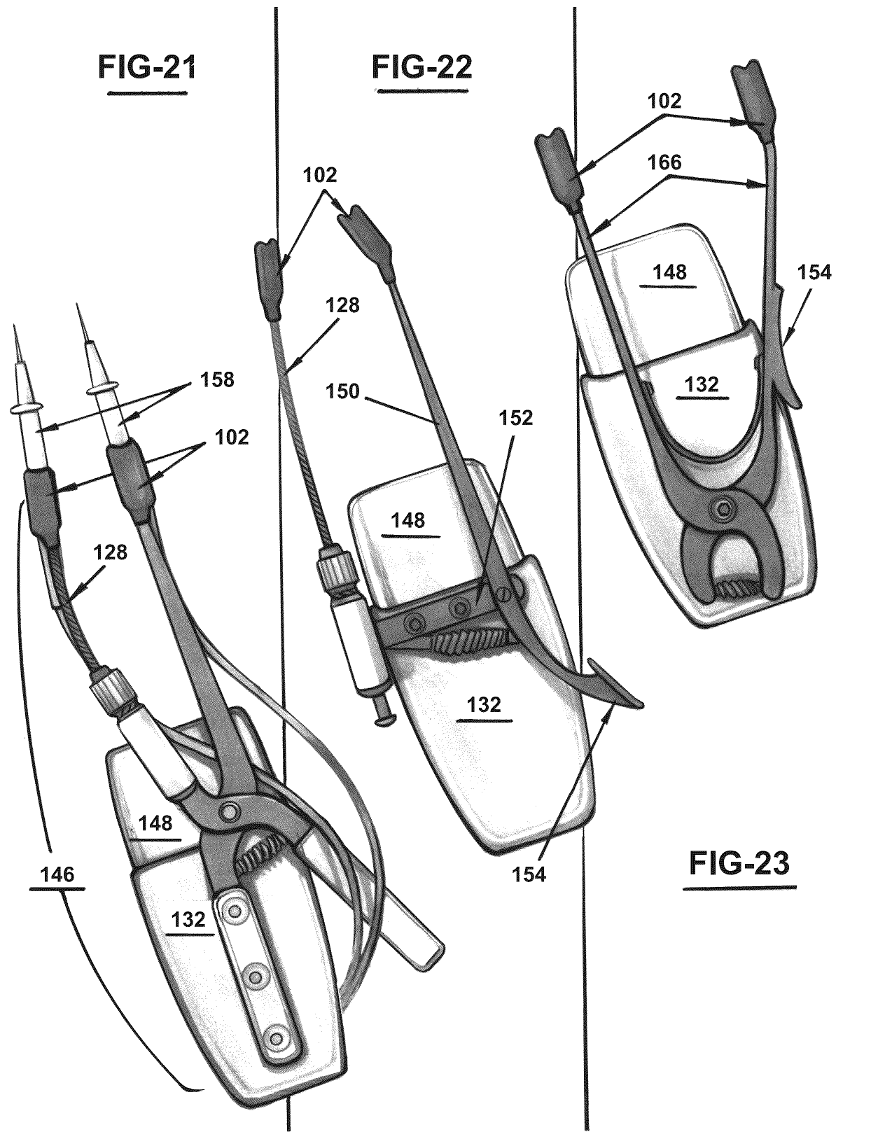

FIG. 23 illustrates a rearward view of the ‘tongs style’ embodiment of the test leads holder apparatus. The test leads clips 102 and the pivoting leads holder arms 166 pivot closer together when the user presses the Lever 154. A typical voltmeter/multimeter 148 is placed in the adapter/holder 132, which is attached to the pivoting leads holder arms. This creates a tongs style embodiment of the one handed test leads holder apparatus. The typical test leads (not shown) can be attached to the test lead clips 102.

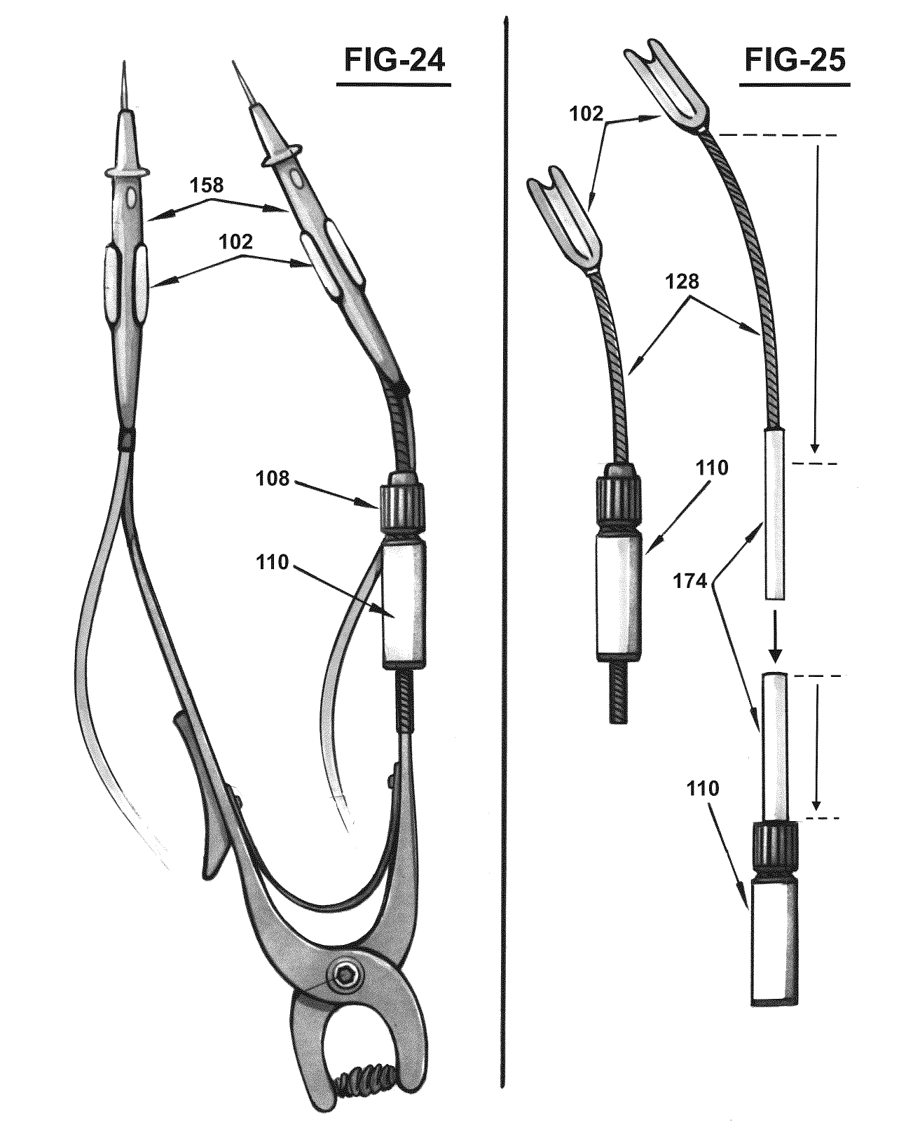

FIG. 24 illustrates a front view of the ‘tongs style’ embodiment of the one handed test leads holder apparatus. FIG. 24 is an alternative embodiment of the ‘tongs style’ embodiment illustrated in FIG. 13. This embodiment of FIG. 24 with the test leads holder apparatus has one flexible and extendable arm with a tightening nut 108 and sleeve 110. The tongs style embodiment shown here could just as easily be fitted with an extendable flexible arm and sleeve on both arms of the apparatus. Two test leads 158 are attached to the non-metallic clips 102. The test lead wires attach to a voltmeter (not shown).

FIG. 25 illustrates a front view of the lead holders 102 which are affixed to the short flexible extension arms 128. The tightening nut 108 releases the pressure on the flexible extension arm 128, and the telescoping extension tubes 174, which are kept in the extendable arm sleeve 110. The telescoping extension tubes 174 can extend out of the sleeve to provide additional reach for the extension arm 128, which can be part of the test leads holder apparatus that is illustrated in FIG. 24.

FIG. 1A through FIG. 10 (and FIG. 21) all share the same ‘scissor’ style mechanism for the lead holder arms. FIG. 11A through FIG. 12 also share the same scissor style mechanism, except that both lead holder arms flex, extend and telescope. FIGS. 13, 14, and 23-25 all share the same ‘tongs’ style mechanism for the lead holder arms. FIGS. 15, 16, 17, 18, 20 and 22; all share the same ‘frame’ style mechanism for the lead holder arms.

### Flexible, Extendable, and Telescoping Leads:

All three different embodiments of the ‘one-handed test leads holder’ tool/apparatus can be fitted with the either stationary, flexible, extendable, or telescoping leads holders. The flexible, extendable, or telescoping leads holders can be affixed, or attached, to either arm.

### One, or Two Flexible Extendable Arms:

Depending on the needs of a user, different embodiments may have either one or both arms fitted with flexible, extendable, or telescoping leads holders. FIG. 1A through FIG. 10 depict an embodiment that has one solid stationary arm 106, while the other arm has a flexible arm 104, and an extendable arm sleeve 110. Embodiments of the tool can be used effectively having no flexible arms, having just one flexible extendable arm, or a combination of flexible, extendable, and or removable arms. Having two flexible extendable arms is not always necessary for the testing purposes of users, because one test point is often safely within reach, while the other test point might be further away, or at an angle that requires a more adjustable positioning of the test lead for good and safe contact with a test point.

In various embodiments described herein, electrical test tools include a one handed test leads holder tool and apparatus having a test leads holder of a test instrument (e.g., voltage meter, voltmeter) for one handed testing of an electrical device.

For Example 1, a one handed test leads holder tool, comprises a first arm having a first holder at a distal region (e.g., near a distal end) to hold a first test lead, a second flexible arm having an extendable or removable arm and a second holder at a distal region (e.g., near a distal end) to hold a second test lead, a first handle for the first arm, a second handle for the second flexible arm, and a pivot to pivotally couple the first arm to the second flexible arm to allow a user to control positioning of the first test lead and the second test lead with one hand while holding the first and second handles to test electrical parameters of an electrical device without having electrical current accidentally entering or passing through a body of the user.

Example 2 includes the subject matter of Example 1, further comprising a nut to lock or unlock the extendable or removable arm of the second flexible arm.

Example 3 includes the subject matter of any of Examples 1-2, further comprising a biasing mechanism to provide a resistant pressure to control a spacing between the first arm and associated first holder and the second arm and associated second holder.

Example 4 includes the subject matter of any of Examples 1-3, further comprising adapter holes of the first handle for attaching the one handed test leads holder tool to an adapter or a holder that is designed to hold a test instrument including a voltage meter for testing the electrical parameters of the electrical device.

Example 5 includes the subject matter of any of Examples 1-4, wherein a spacing between the first test lead and the second test lead is adjustable by applying pressure to the first handle or the second handle.

Example 6 includes the subject matter of any of Examples 1-5, wherein the second flexible arm is pliable, bendable, and yet made of stiff material to allow angular adjustment for reaching electrical test points.

Example 7 includes the subject matter of any of Examples 1-6, further comprising a first sleeve attached to the first arm, the sleeve to hold an extendable arm of the first arm to store additional length for the first arm. The extendable arm is capable of telescoping out or being retracted into the first sleeve; and a second sleeve attached to the second flexible arm. The sleeve to hold the extendable arm of the second flexible arm to store additional length for the second flexible arm. The extendable arm is capable of telescoping out or being retracted into the sleeve.

Some embodiments relate to Example 8 that includes a one handed holder apparatus, comprising a first elongated arm having a first holder at a first distal region (e.g., near a distal end) to hold a first test lead, a second elongated arm having a second holder at a first distal region (e.g., near a distal end) to hold a second test lead, a lever disposed on the first elongated arm or the second elongated arm, and a pivot to pivotally couple the first elongated arm to the second elongated arm to allow a user to control positioning of the first test lead and the second test lead with one hand based on pressing or releasing of the lever to test electrical parameters of an electrical device without having electrical current accidentally entering or passing through a body of the user.

Example 9 includes the subject matter of Example 8, further comprising an adapter to hold a test instrument including a voltage meter and being capable of attachment to the pivot.

Example 10 includes the subject matter of any of Examples 8-9, further comprising a first sleeve attached to the first elongated arm. The first sleeve to hold an extendable arm of the first elongated arm to store additional length for the first elongated arm. The extendable arm is capable of telescoping out or being retracted into the first sleeve.

Example 11 includes the subject matter of any of Examples 8-10, further comprising a second sleeve attached to the second elongated arm. The second sleeve to hold an extendable arm of the second elongated arm to store additional length for the second elongated arm. The extendable arm is capable of telescoping out or being retracted into the sleeve.

Example 12 includes the subject matter of any of Examples 8-11, further comprising a nut to lock or unlock an extendable arm of the first or second elongated arm.

Example 13 includes the subject matter of any of Examples 8-12, wherein a spacing between the first test lead and the second test lead is adjustable by applying pressure to the lever while the user holds the one handed test apparatus and the test instrument with one hand.

Some embodiments relate to Example 14 that includes a test leads holder for attachment to a handheld test instrument, comprising an adapter frame; a test lead holder arm to pivot with respect to the adapter frame via a pivot and being adapted at a first distal region to hold a first test lead.

An extendable holder arm is adapted to hold a second test lead and a lever is formed at a second distal region of the test lead holder arm. A user adjusts a spacing between the first distal region of the test lead holder arm and a distal region of the extendable holder arm by pressing or releasing the lever with a digit of one hand to control a position of the first test lead and the second test lead to test voltage of an electrical device without having electrical current accidentally entering or passing through a body of the user.

Example 15 includes the subject matter of Example 14, further comprising a sleeve that is attached to the frame to support the extendable holder arm, the sleeve to hold an extendable arm of the extendable holder arm to store additional length for the extendable holder arm, wherein the extendable arm is capable of telescoping out or being retracted into the sleeve; a nut to lock or unlock the extendable arm of the extendable holder arm; and an adapter holder that is adapted to hold a test instrument.

Example 16 includes the subject matter of any of Examples 14-15, further comprising, wherein the adapter holder is adapted to attach to the adapter frame with one or more adapter bolts.

Example 17 includes the subject matter of any of Examples 14-16, further comprising a spring to be disposed between a lower portion of the test lead holder arm that is below the adapter frame and one end of the adapter frame to bias a position of the test lead holder arm.

Example 18 includes the subject matter of any of Examples 14-17, wherein the extendable holder arm is pliable, bendable, and yet made of stiff material to allow angular adjustment for reaching electrical test points.

Example 19 includes the subject matter of any of Examples 14-18, wherein the adapter frame comprises holes for one or more adapter bolts.

Example 20 includes the subject matter of any of Examples 14-18, wherein the adapter frame comprises a hole for the pivot.

In the foregoing specification, embodiments have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A one handed test leads holder tool, comprising:
a first arm having a first holder at a distal region to hold a first test lead;
a second flexible arm having an extendable or removable arm and a second holder at a distal region to hold a second test lead;
a first handle for the first arm;
a second handle for the second flexible arm; and
a pivot to pivotally couple the first arm to the second flexible arm to allow a user to control positioning of the first test lead and the second test lead with one hand while holding the first and second handles to test electrical parameters of an electrical device without having electrical current accidentally entering or passing through a body of the user.

2. The one handed test leads holder tool of claim 1, further comprising:
a nut to lock or unlock the extendable or removable arm of the second flexible arm.

3. The one handed test leads holder tool of claim 1, further comprising:
a biasing mechanism to provide a resistant pressure to control a spacing between the first arm and associated first holder and the second arm and associated second holder.

4. The one handed test leads holder tool of claim 1, further comprising:
adapter holes of the first handle for attaching the one handed test leads holder tool to an adapter or a holder that is designed to hold a test instrument including a voltage meter for testing the electrical parameters of the electrical device.

5. The one handed test leads holder tool of claim 4, wherein a spacing between the first test lead and the second test lead is adjustable by applying pressure to the first handle or the second handle.

6. The one handed test leads holder tool of claim 1, wherein the second flexible arm is pliable, bendable, and yet made of stiff material to allow angular adjustment for reaching electrical test points.

7. The one handed test leads holder tool of claim 1, further comprising:
a first sleeve attached to the first arm, the sleeve to hold an extendable arm of the first arm to store additional length for the first arm, wherein the extendable arm is capable of telescoping out or being retracted into the first sleeve; and
a second sleeve attached to the second flexible arm, the sleeve to hold the extendable arm of the second flexible arm to store additional length for the second flexible arm, wherein the extendable arm is capable of telescoping out or being retracted into the sleeve.

8. A one handed holder apparatus, comprising:
a first elongated arm having a first holder at a distal region to hold a first test lead;
a second elongated arm having a second holder at a distal region to hold a second test lead;
a lever disposed on the first elongated arm or the second elongated arm; and
a pivot to pivotally couple the first elongated arm to the second elongated arm to allow a user to control positioning of the first test lead and the second test lead with one hand based on pressing or releasing of the lever to test electrical parameters of an electrical device without having electrical current accidentally entering or passing through a body of the user.

9. The one handed holder apparatus of claim 8, further comprising:
an adapter to hold a test instrument including a voltage meter and being capable of attachment to the one handed holder apparatus.

10. The one handed holder apparatus of claim 8, further comprising:
a first sleeve attached to the first elongated arm, the first sleeve to hold an extendable arm of the first elongated arm to store additional length for the first elongated arm, wherein the extendable arm is capable of telescoping out or being retracted into the first sleeve.

11. The one handed holder apparatus of claim 8, further comprising:
a second sleeve attached to the second elongated arm, the second sleeve to hold an extendable arm of the second elongated arm to store additional length for the second elongated arm, wherein the extendable arm is capable of telescoping out or being retracted into the sleeve.

12. The one handed holder apparatus of claim 8, further comprising:
a nut to lock or unlock an extendable arm of the first or second elongated arm.

13. The one handed holder apparatus of claim 8, wherein the second elongated arm is pliable, bendable, and yet made of stiff material to allow angular adjustment for reaching electrical test points.

14. A test leads holder for attachment to a handheld test instrument, comprising:
an adapter frame;
a test lead holder arm to pivot with respect to the adapter frame via a pivot and being adapted at a first distal region to hold a first test lead;
an extendable holder arm being adapted to hold a second test lead; and
a lever formed at a second distal region of the test lead holder arm, wherein a user adjusts a spacing between the first distal region of the test lead holder arm and a distal region of the extendable holder arm by pressing or releasing the lever with a digit of one hand to control a position of the first test lead and the second test lead to test voltage of an electrical device without having electrical current accidentally entering or passing through a body of the user.

15. The test leads holder of claim 14, further comprising:
a sleeve that is attached to the frame to support the extendable holder arm, the sleeve to hold an extendable arm of the extendable holder arm to store additional length for the extendable holder arm, wherein the extendable arm is capable of telescoping out or being retracted into the sleeve;
a nut to lock or unlock the extendable arm of the extendable holder arm;
and
an adapter holder that is adapted to hold a test instrument.

16. The test leads holder of claim 15, wherein the adapter holder is adapted to attach to the adapter frame with one or more adapter bolts.

17. The test leads holder of claim 14, further comprising:
a spring to be disposed between a lower portion of the test lead holder arm that is below the adapter frame and one end of the adapter frame to bias a position of the test lead holder arm.

18. The test leads holder of claim 14, wherein the extendable holder arm is pliable, bendable, and yet made of stiff material to allow angular adjustment for reaching electrical test points.

19. The test leads holder of claim 14, wherein the adapter frame comprises holes for one or more adapter bolts.

20. The test leads holder of claim 14, wherein the adapter frame comprises a hole for the pivot.
